(19) United States
(12) Patent Application Publication
(10) Pub. No.: US 2015/0147889 A1
(43) Pub. Date: May 28, 2015

(54) Tilted Plate For Batch Processing And Methods Of Use

(71) Applicant: Applied Materials, Inc., Santa Clara, CA (US)

(72) Inventors: Joseph Yudovsky, Campbell, CA (US); Kevin Griffin, Livermore, CA (US)

(21) Appl. No.: 14/546,078

(22) Filed: Nov. 18, 2014

Related U.S. Application Data
(60) Provisional application No. 61/909,291, filed on Nov. 26, 2013.

(51) Int. Cl. C23C 16/455; C23C 16/458; H01L 21/02; C23C 16/52

(52) U.S. Cl. CPC C23C 16/45593; C23C 16/52; C23C 16/4584; H01L 21/0228
USPC 438/758; 118/730

(57) ABSTRACT

A substrate processing chamber and methods for processing multiple substrates is provided and generally includes a gas distribution assembly, a susceptor assembly to rotate substrates along a path adjacent each of the gas distribution assembly and a gas diverter to change the angle of gas flow in the processing chamber.

### CROSS-REFERENCE TO RELATED APPLICATIONS

This application claims priority to U.S. Provisional Application No. 61/909,291, filed Nov. 26, 2013.

### TECHNICAL FIELD

Embodiments of the present invention generally relate to an apparatus for processing substrates. More particularly, the invention relates to a batch processing platform for performing atomic layer deposition (ALD) and chemical vapor deposition (CVD) on substrates.

### BACKGROUND

The process of forming semiconductor devices is commonly conducted in substrate processing platforms containing multiple chambers. In some instances, the purpose of a multi-chamber processing platform or cluster tool is to perform two or more processes on a substrate sequentially in a controlled environment. In other instances, however, a multiple chamber processing platform may only perform a single processing step on substrates; the additional chambers are intended to maximize the rate at which substrates are processed by the platform. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for ALD processes and some chemical vapor deposition (CVD) processes.

The effectiveness of a substrate processing platform, or system, is often quantified by cost of ownership (COO). The COO, while influenced by many factors, is largely affected by the system footprint, i.e., the total floor space required to operate the system in a fabrication plant, and system throughput, i.e., the number of substrates processed per hour. Footprint typically includes access areas adjacent the system that are required for maintenance. Hence, although a substrate processing platform may be relatively small, if it requires access from all sides for operation and maintenance, the system's effective footprint may still be prohibitively large.

The semiconductor industry's tolerance for process variability continues to decrease as the size of semiconductor devices shrink. To meet these tighter process requirements, the industry has developed a host of new processes which meet the tighter process window requirements, but these processes often take a longer time to complete. For example, for forming a copper diffusion barrier layer conformally onto the surface of a high aspect ratio, 65 nm or smaller interconnect feature, it may be necessary to use an ALD process. ALD is a variant of CVD that demonstrates superior step coverage compared to CVD. ALD is based upon atomic layer epitaxy (ALE) that was originally employed to fabricate electroluminescent displays. ALD employs chemisorption to deposit a saturated monolayer of reactive precursor molecules on a substrate surface. This is achieved by cyclically alternating the pulsing of appropriate reactive precursors into a deposition chamber. Each injection of a reactive precursor is typically separated by an inert gas purge to provide a new atomic layer to previous deposited layers to form a uniform material layer on the surface of a substrate. Cycles of reactive precursor and inert purge gases are repeated to form the material layer to a chosen thickness. The biggest drawback with ALD techniques is that the deposition rate is much lower than typical CVD techniques by at least an order of magnitude. For example, some ALD processes can require a chamber processing time from about 10 to about 200 minutes to deposit a high quality layer on the surface of the substrate. In choosing such ALD and epitaxy processes for better device performance, the cost to fabricate devices in a conventional single substrate processing chamber would increase due to very low substrate processing throughput. Hence, when implementing such processes, a continuous substrate processing approach is needed to be economically feasible.

There is an ongoing need in the art for apparatus and methods of uniformly depositing a film on a substrate in an efficient and cost effective manner.

### SUMMARY

Embodiments of the invention are directed to a processing chamber comprising a gas distribution assembly, susceptor assembly and a diverter. The circular gas distribution assembly is positioned within the processing chamber and comprises a plurality of elongate gas ports in a front face of the gas distribution assembly. The plurality of elongate gas ports extending from an inner diameter region to an outer diameter region of the gas distribution assembly, the plurality of gas ports comprising a reactive gas port to deliver a reactive gas to the processing chamber, a purge gas port to deliver a purge gas to the processing chamber and a vacuum port to evacuate gases from the processing chamber. The susceptor assembly is within the processing chamber to rotate at least one substrate in a substantially circular path about a rotational axis. The susceptor assembly having a top surface defined by an inner peripheral edge and an outer peripheral edge, the susceptor assembly positioned below the gas distribution assembly so that the top surface of the susceptor assembly faces the front face of the gas distribution assembly. The diverter positioned to change the flow direction of the reactive gas so that when a substrate is on the susceptor assembly, the reactive gas contacts a surface of the substrate at an angle of less than about 90° relative to the substrate surface.

Additional embodiments of the invention are directed to methods of processing a plurality of substrates. A susceptor assembly is rotated in a processing direction to pass each of the plurality of substrates adjacent a front face of a gas distribution assembly to expose the substrates to a flow of reactive gas from the gas distribution assembly. A diverter is controlled to angle the flow of reactive gas to less than about 90° relative to the substrate surface.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional side view of a spatial atomic layer deposition chamber in accordance with one or more embodiment of the invention;

FIG. 2 shows a perspective view of a susceptor in accordance with one or more embodiments of the invention;

FIG. 3 shows a schematic of a pie-shaped gas distribution assembly in accordance with one or more embodiments of the invention;

FIG. 4 is a schematic plan view of a substrate processing system configured with four gas distribution assembly units with a loading station in accordance with one or more embodiments of the invention;

FIG. 5 is a schematic plan view of a substrate processing system configured with three gas distribution assembly units;

FIG. 6 shows a cross-sectional view of a processing chamber in accordance with one or more embodiments of the invention;

FIG. 7 shows a perspective view of a susceptor assembly and gas distribution assembly units in accordance with one or more embodiments of the invention;

FIG. 8 shows a cross-sectional view of a processing chamber in accordance with one or more embodiments of the invention;

FIG. 9 shows a schematic of a pie-shaped gas distribution assembly in accordance with one or more embodiments of the invention;

FIG. 10 shows a perspective view of a gas distribution assembly with a gas diverter in accordance with one or more embodiments of the invention;

FIG. 11 shows a perspective view of a gas diverter in accordance with one or more embodiments; and

FIG. 12 shows a cross-sectional view of a gas distribution assembly with a gas diverter in accordance with one or more embodiments of the invention.

### DETAILED DESCRIPTION

Embodiments of the invention provide a substrate processing system for continuous substrate deposition to maximize throughput and improve processing efficiency and uniformity. The substrate processing system can also be used for pre-deposition and post-deposition substrate treatments. Embodiments of the invention are related to apparatus and methods for increasing deposition uniformity in a batch processor.

Current deposition apparatus level the injector assembly relative to the susceptor assembly/wafer surface so that there is a uniform gap from the inner peripheral edge to the outer peripheral edge. In some processing conditions, deposition non-uniformity occurs across the wafer. It is believed that this results from the uniform spacing extending radially from the inner peripheral edge to the outer peripheral edge of the susceptor assembly.

Embodiments of the invention help tune or increase the deposition uniformity and film quality achieved in a batch processor. A plate or insert for a showerhead module has been designed to adjust the spacing from the susceptor assembly/wafer in both the radial and tangential directions. The degree of tilt of the plate, in both the radial and tangential directions can be manually or automatically adjusted.

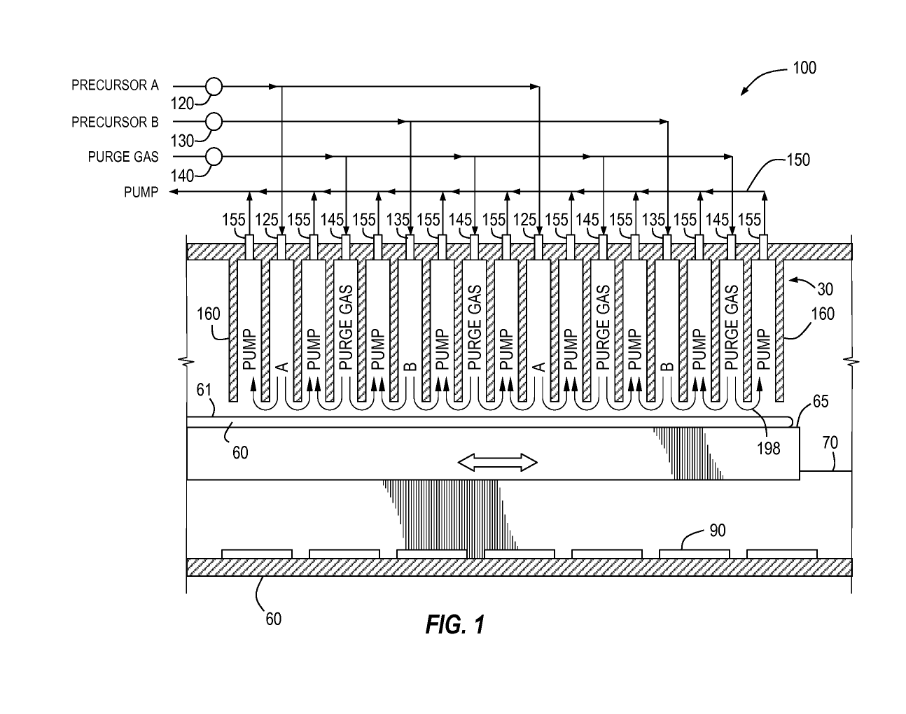

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. For example, in spatially separated ALD, described with respect to FIG. 1, each precursor is delivered to the substrate, but any individual precursor stream, at any given time, is only delivered to a portion of the substrate. Additionally, reference to depositing on a substrate can mean both a bare substrate and a substrate with one or more films or features deposited or formed thereon.

As used in this specification and the appended claims, the terms “reactive gas”, “precursor”, “reactant”, and the like, are used interchangeably to mean a gas that includes a species which is reactive in an atomic layer deposition process. For example, a first “reactive gas” may simply adsorb onto the surface of a substrate and be available for further chemical reaction with a second reactive gas.

FIG. 1 is a schematic cross-sectional view of a portion of a processing chamber 20 in accordance with one or more embodiments of the invention. The processing chamber 20 is generally a sealable enclosure, which is operated under vacuum or at least low pressure conditions. The system includes a gas distribution assembly 30 capable of distributing one or more gases across the top surface 61 of a substrate 60. The gas distribution assembly 30 can be any suitable assembly known to those skilled in the art, and specific gas distribution assemblies described should not be taken as limiting the scope of the invention. The output face of the gas distribution assembly 30 faces the first surface 61 of the substrate 60.

Substrates for use with the embodiments of the invention can be any suitable substrate. In some embodiments, the substrate is a rigid, discrete, generally planar substrate. As used in this specification and the appended claims, the term “discrete” when referring to a substrate means that the substrate has a fixed dimension. The substrate of one or more embodiments is a semiconductor substrate, such as a 200 mm or 300 mm diameter silicon substrate. In some embodiments, the substrate is one or more of silicon, silicon germanium, gallium arsenide, gallium nitride, germanium, gallium phosphide, indium phosphide, sapphire and silicon carbide.

The gas distribution assembly 30 comprises a plurality of gas ports to transmit one or more gas streams to the substrate 60 and a plurality of vacuum ports disposed between each gas port to transmit the gas streams out of the processing chamber 20. In the embodiment of FIG. 1, the gas distribution assembly 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 injects a continuous (or pulse) stream of a reactive precursor of compound A into the processing chamber 20 through a plurality of gas ports 125. The precursor injector 130 injects a continuous (or pulse) stream of a reactive precursor of compound B into the processing chamber 20 through a plurality of gas ports 135. The purge gas injector 140 injects a continuous (or pulse) stream of a non-reactive or purge gas into the processing chamber 20 through a plurality of gas ports 145. The purge gas removes reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the processing chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high energy light source (e.g., UV energy), or exposure to an x-ray source. Exemplary remote plasma sources are available from vendors such as MKS Instruments, Inc. and Advanced Energy Industries, Inc.

The system further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system includes a plurality of partitions 160 disposed on the processing chamber 20 between each port. A lower portion of each partition extends close to the first surface 61 of substrate 60, for example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution assemblies may be employed.

Atomic layer deposition systems of this sort (i.e., where multiple gases are separately flowed toward the substrate at the same time) are referred to as spatial ALD. In operation, a substrate 60 is delivered (e.g., by a robot) to the processing chamber 20 and can be placed on a shuttle 65 before or after entry into the processing chamber. The shuttle 65 is moved along the track 70, or some other suitable movement mechanism, through the processing chamber 20, passing beneath (or above) the gas distribution assembly 30. In the embodiment shown in FIG. 1, the shuttle 65 is moved in a linear path through the chamber. FIG. 3, as explained further below, shows an embodiment in which wafers are moved in a circular path through a carousel processing system.

Referring back to FIG. 1, as the substrate 60 moves through the processing chamber 20, the first surface 61 of substrate 60 is repeatedly exposed to the reactive gas A coming from gas ports 125 and reactive gas B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the reactive gases or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps and can occur while the substrate is passing beneath the gas distribution assembly 30 or when the substrate is in a region before and/or after the gas distribution assembly 30.

Sufficient space is generally provided after the gas distribution assembly 30 to ensure complete exposure to the last gas port. Once the substrate 60 has completely passed beneath the gas distribution assembly 30, the first surface 61 has completely been exposed to every gas port in the processing chamber 20. The substrate can then be transported back in the opposite direction or forward. If the substrate 60 moves in the opposite direction, the substrate surface may be exposed again to the reactive gas A, the purge gas, and reactive gas B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are controlled so as not to remove adsorbed precursors from the substrate surface 61. The width between each partition, the number of gas ports disposed on the processing chamber 20, and the number of times the substrate is passed across the gas distribution assembly may also determine the extent to which the substrate surface 61 is exposed to the various gases. Consequently, the quantity and quality of a deposited film may be optimized by varying the above-referenced factors.

Although description of the process has been made with the gas distribution assembly 30 directing a flow of gas downward toward a substrate positioned below the gas distribution assembly, it will be understood that this orientation can be different. In some embodiments, the gas distribution assembly 30 directs a flow of gas upward toward a substrate surface. As used in this specification and the appended claims, the term “passed across” means that the substrate has been moved from one side of the gas distribution assembly to the other side so that the entire surface of the substrate is exposed to each gas stream from the gas distribution plate. Absent additional description, the term “passed across” does not imply any particular orientation of gas distribution assemblies, gas flows or substrate positions.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) or in a circular direction (relative to FIG. 3). The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

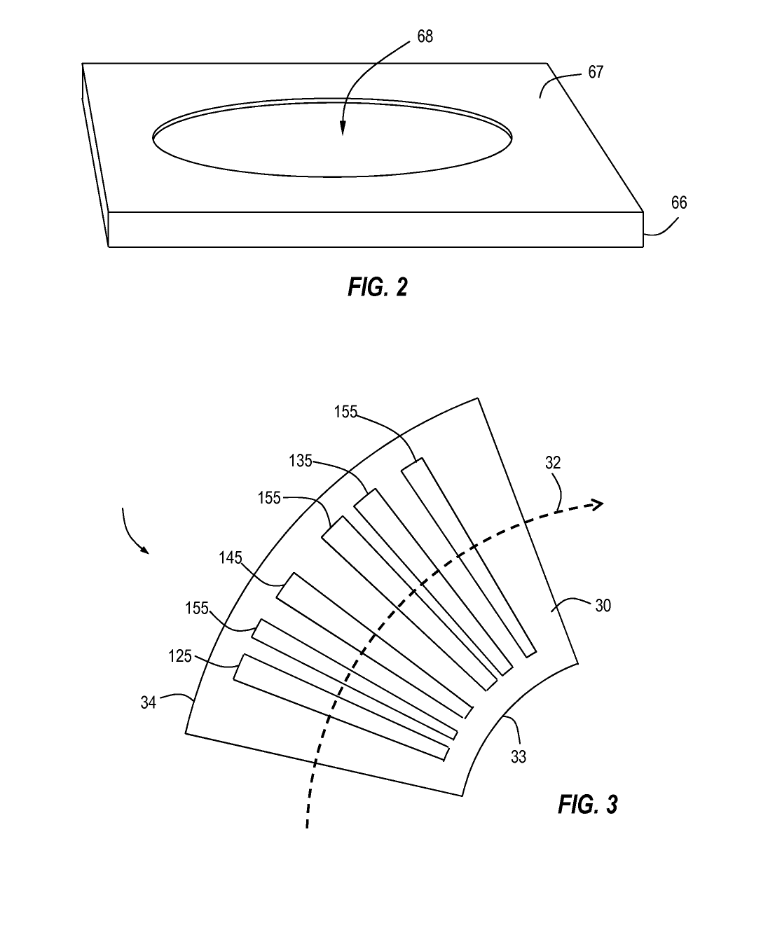

In still another embodiment, the top surface 67 of the susceptor 66 includes a recess 68 to accept the substrate 60, as shown in FIG. 2. The susceptor 66 is generally thicker than the thickness of the substrate so that there is susceptor material beneath the substrate. In some embodiments, the recess 68 is sized such that when the substrate 60 is disposed inside the recess 68, the first surface 61 of substrate 60 is level with, or substantially coplanar with, the top surface 67 of the susceptor 66. Stated differently, the recess 68 of some embodiments is sized such that when a substrate 60 is disposed therein, the first surface 61 of the substrate 60 does not protrude above the top surface 67 of the susceptor 66. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

FIG. 1 shows a cross-sectional view of a processing chamber in which the individual gas ports are shown. This embodiment can be either a linear processing system in which the width of the individual gas ports is substantially the same across the entire width of the gas distribution plate, or a pie-shaped segment in which the individual gas ports change width to conform to the pie shape. FIG. 3 shows a portion of a pie-shaped gas distribution assembly 30. A substrate would be passed across this gas distribution assembly 30 in an arc shape path 32. Each of the individual gas ports 125, 135, 145, 155 have a narrower width near the inner peripheral edge 33 of the gas distribution assembly 30 a and a larger width near the outer peripheral edge 34 of the gas distribution assembly 30. The shape or aspect ratio of the individual ports can be proportional to, or different from, the shape or aspect ratio of the gas distribution assembly 30 segment. In some embodiments, the individual ports are shaped so that each point of a wafer passing across the gas distribution assembly 30 following path 32 would have about the same residence time under each gas port. The path of the substrates can be perpendicular to the gas ports. In some embodiments, each of the gas distribution assemblies comprises a plurality of elongate gas ports which extend in a direction substantially perpendicular to the path traversed by a substrate. As used in this specification and the appended claims, the term “substantially perpendicular” means that the general direction of movement is approximately perpendicular to the axis of the gas ports. For a pie-shaped gas port, the axis of the gas port can be considered to be a line defined as the mid-point of the width of the port extending along the length of the port. As described further below, each of the individual pie-shaped segments can be configured to deliver a single reactive gas or multiple reactive gases separated spatially or in combination (e.g., as in a typical CVD process).

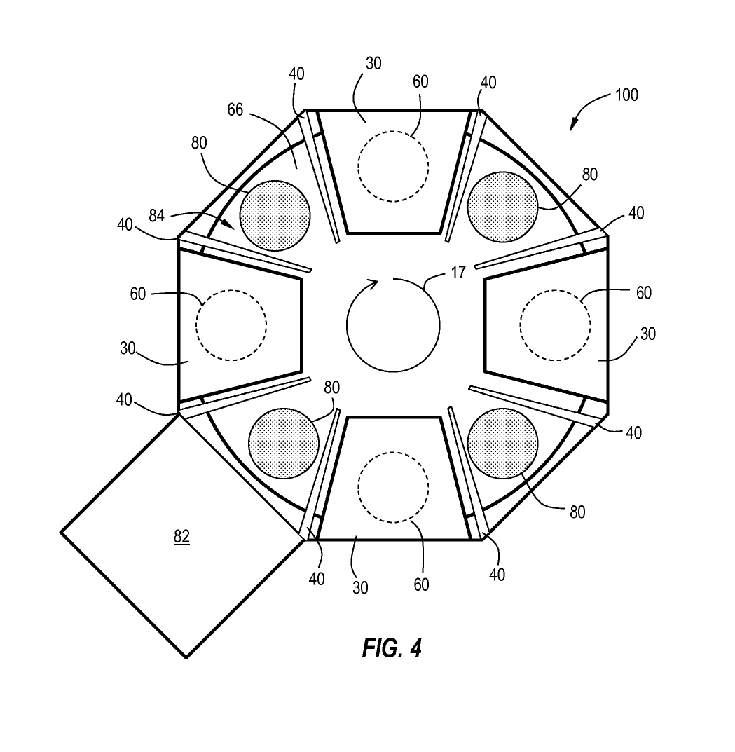

Processing chambers having multiple gas injectors can be used to process multiple wafers simultaneously so that the wafers experience the same process flow. For example, as shown in FIG. 4, the processing chamber 100 has four gas distribution assemblies 30 (also called injector assemblies) and four substrates 60. At the outset of processing, the substrates 60 can be positioned between the gas distribution assemblies 30 (also called injector assemblies). Rotating the susceptor 66 of the carousel by 45° will result in each substrate 60 being moved to an gas distribution assembly 30 (also called an injector assembly) for film deposition. This is the position shown in FIG. 4. An additional 45° rotation would move the substrates 60 away from the gas distribution assemblies 30 (also called injector assemblies). With spatial ALD injectors, a film is deposited on the wafer during movement of the wafer relative to the injector assembly. In some embodiments, the susceptor 66 is rotated so that the substrates 60 do not stop beneath the gas distribution assemblies 30 (also called injector assemblies). The number of substrates 60 and gas distribution assemblies 30 can be the same or different. In some embodiments, there is the same number of wafers being processed as there are gas distribution assemblies. In one or more embodiments, the number of wafers being processed are an integer multiple of the number of gas distribution assemblies. For example, if there are four gas distribution assemblies, there are 4x wafers being processed, where x is an integer value greater than or equal to one.

The processing chamber 100 shown in FIG. 4 is merely representative of one possible configuration and should not be taken as limiting the scope of the invention. Here, the processing chamber 100 includes a plurality of gas distribution assemblies 30. In the embodiment shown, there are four gas distribution assemblies 30 evenly spaced about the processing chamber 100. The processing chamber 100 shown is octagonal, however, it will be understood by those skilled in the art that this is one possible shape and should not be taken as limiting the scope of the invention. The gas distribution assemblies 30 shown are rectangular, but it will be understood by those skilled in the art that the gas distribution assemblies can be pie-shaped segments, like that shown in FIG. 3. Additionally, each segment can be configured to deliver gases in a spatial type arrangement with multiple different reactive gases flowing from the same segment or configured to deliver a single reactive gas or a mixture of reactive gases.

The processing chamber 100 includes a substrate support apparatus, shown as a round susceptor 66 or susceptor assembly. The substrate support apparatus, or susceptor 66, is capable of moving a plurality of substrates 60 beneath each of the gas distribution assemblies 30. A load lock 82 might be connected to a side of the processing chamber 100 to allow the substrates 60 to be loaded/unloaded from the chamber 100.

The processing chamber 100 may include a plurality, or set, of first treatment stations 80 positioned between any or each of the plurality of gas distribution assemblies 30. In some embodiments, each of the first treatment stations 80 provides the same treatment to a substrate 60.

The number of treatment stations and the number of different types of treatment stations can vary depending on the process. For example, there can be one, two, three, four, five, six, seven or more treatment stations positioned between the gas distribution assemblies 30. Each treatment stations can independently provide a different treatment from every other set of treatments station, or there can be a mixture of the same type and different types of treatments. In some embodiments, one or more of the individual treatments stations provides a different treatment than one or more of the other individual treatment stations.

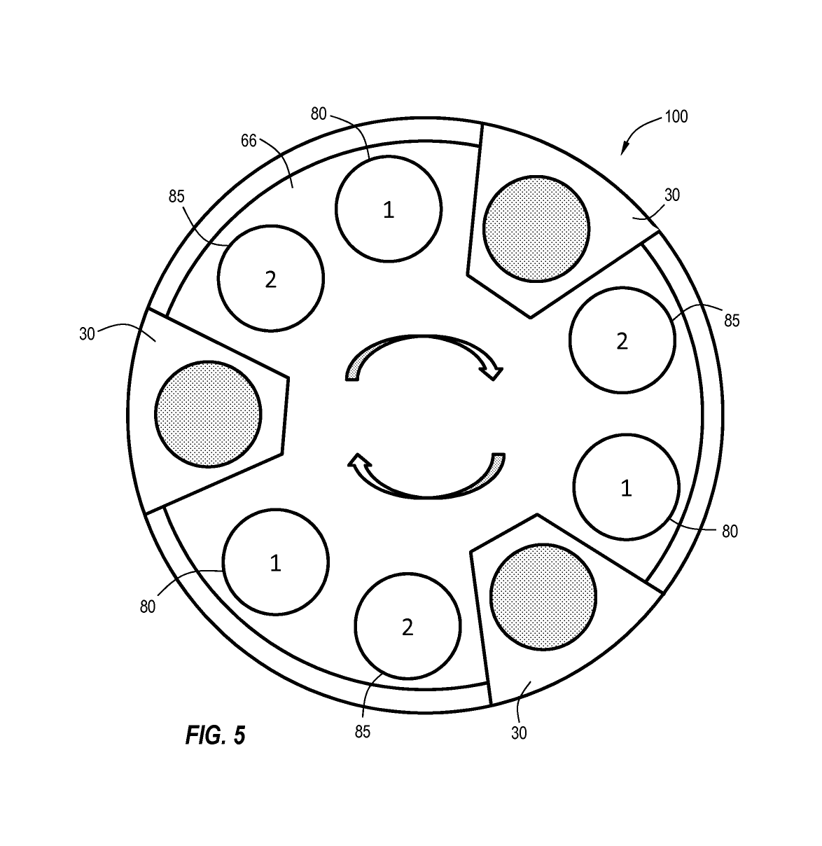

In the embodiment shown in FIG. 5, a set of second treatment stations 85 are positioned between the first treatment stations 80 and the gas distribution assemblies 30 so that a substrate 60 rotated through the processing chamber 100 would encounter, depending on where the substrate 60 starts, a gas distribution assembly 30, a first treatment station 80 and a second treatment station 85 before encountering a second of any of these. For example, as shown in FIG. 5, if the substrate started at the first treatment station 80, it would see, in order, the first treatment station 80, a gas distribution assembly 30 and a second treatment station 85 before encountering a second first treatment station 85.

Treatment stations can provide any suitable type of treatment to the substrate, film on the substrate or susceptor assembly. For example, UV lamps, flash lamps, plasma sources and heaters. The wafers are then moved between positions with the gas distribution assemblies 30 to a position with, for example, a showerhead delivering plasma to the wafer. The plasma station being referred to as a treatment station 80. In one or more example, silicon nitride films can be formed with plasma treatment after each deposition layer. As the ALD reaction is, theoretically, self-limiting as long as the surface is saturated, additional exposure to the deposition gas will not cause damage to the film.

Rotation of the carousel can be continuous or discontinuous. In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where it can pause again. Pausing between the injectors may provide time for additional processing steps between each layer deposition (e.g., exposure to plasma).

In some embodiments, the processing chamber comprises a plurality of gas curtains 40. Each gas curtain 40 creates a barrier to prevent, or minimize, the movement of processing gases from the gas distribution assemblies 30 from migrating from the gas distribution assembly regions and gases from the treatment stations 80 from migrating from the treatment station regions. The gas curtain 40 can include any suitable combination of gas and vacuum streams which can isolate the individual processing sections from the adjacent sections. In some embodiments, the gas curtain 40 is a purge (or inert) gas stream. In one or more embodiments, the gas curtain 40 is a vacuum stream that removes gases from the processing chamber. In some embodiments, the gas curtain 40 is a combination of purge gas and vacuum streams so that there are, in order, a purge gas stream, a vacuum stream and a purge gas stream. In one or more embodiments, the gas curtain 40 is a combination of vacuum streams and purge gas streams so that there are, in order, a vacuum stream, a purge gas stream and a vacuum stream. The gas curtains 40 shown in FIG. 4 are positioned between each of the gas distribution assemblies 30 and treatment stations 80, but it will be understood that the curtains can be positioned at any point or points along the processing path.

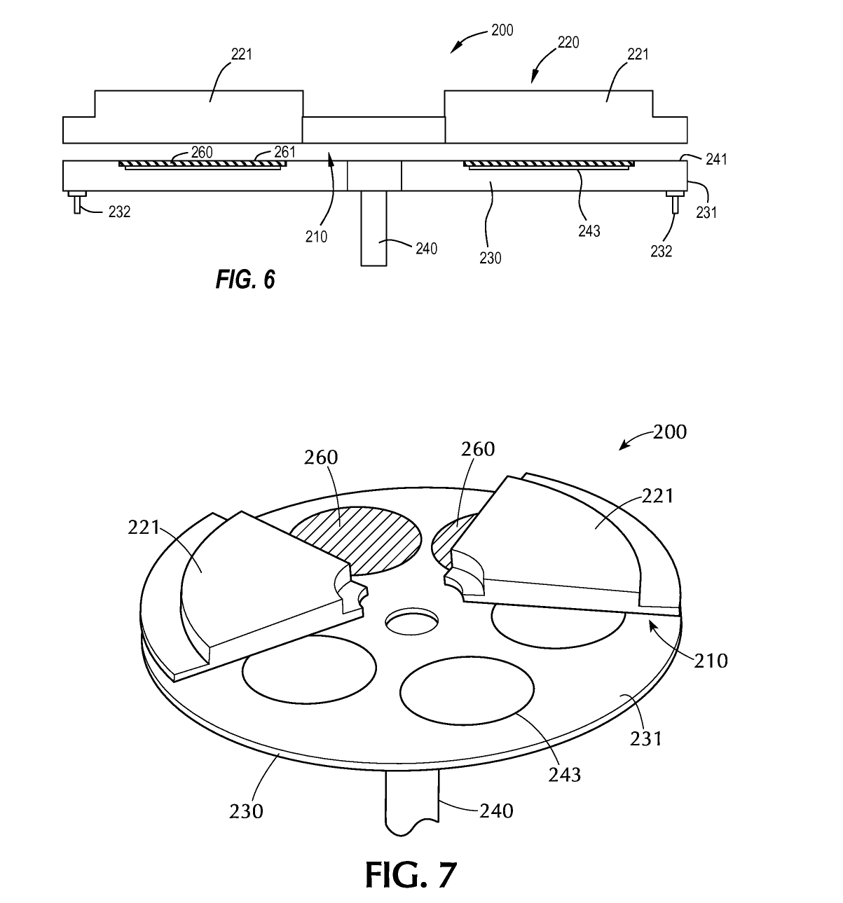

FIG. 6 shows an embodiment of a processing chamber 200 including a gas distribution assembly 220, also referred to as the injectors, and a susceptor assembly 230. In this embodiment, the susceptor assembly 230 is a rigid body. The rigid body of some embodiments has a droop tolerance no larger than 0.05 mm. Actuators 232 are placed, for example, at three locations at the outer diameter region of the susceptor assembly 230. As used in this specification and the appended claims, the terms “outer diameter” and “inner diameter” refer to regions near the outer peripheral edge and the inner edge, respectively. The outer diameter is not to a specific position at the extreme outer edge (e.g., near shaft 240) of the susceptor assembly 230, but is a region near the outer edge 231 of the susceptor assembly 230. This can be seen in FIG. 6 from the placement of the actuators 232. The number of actuators 232 can vary from one to any number that will fit within the physical space available. Some embodiments have two, three, four or five sets of actuators 232 positioned in the outer diameter region 231. As used in this specification and the appended claims, the term “actuator” refers to any single or multi-component mechanism which is capable of moving the susceptor assembly 230, or a portion of the susceptor assembly 230, toward or away from the gas distribution assembly 220. For example, actuators 232 can be used to ensure that the susceptor assembly 230 is substantially parallel to the injector assembly 220. As used in this specification and the appended claims, the term “substantially parallel” used in this regard means that the parallelism of the components does not vary by more than 5% relative to the distance between the components.

Once pressure is applied to the susceptor assembly 230 from the actuators 232, the susceptor assembly 230 can be levelled. As the pressure is applied by the actuators 232, the gap 210 distance can be set to be within the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The susceptor assembly 230 is positioned beneath the gas distribution assembly 220. The susceptor assembly 230 includes a top surface 241 and, optionally, at least one recess 243 in the top surface 241. The recess 243 can be any suitable shape and size depending on the shape and size of the wafers 260 being processed. In the embodiment shown, the recess 243 has a step region around the outer peripheral edge. The steps can be sized to support the outer peripheral edge of the wafer 260. The amount of the outer peripheral edge of the wafer 260 that is supported by the steps can vary depending on, for example, the thickness of the wafer and the presence of features already present on the back side of the wafer.

In some embodiments, as shown in FIG. 6, the recess 243 in the top surface 241 of the susceptor assembly 230 is sized so that a wafer 260 supported in the recess 243 has a top surface 261 substantially coplanar with the top surface 241 of the susceptor assembly 230. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

The susceptor assembly 230 of FIG. 6 includes a support post 240 which is capable of lifting, lowering and rotating the susceptor assembly 230. The susceptor assembly 230 may include a heater, or gas lines, or electrical components within the center of the support post 240. The support post 240 may be the primary means of increasing or decreasing the gap between the susceptor assembly 230 and the gas distribution assembly 220, moving the susceptor assembly 230 into rough position. The actuators 232 can then make micro-adjustments to the position of the susceptor assembly to create the chosen gap.

The processing chamber 100 shown in FIG. 6 is a carousel-type chamber in which the susceptor assembly 230 can hold a plurality of wafers 260. The gas distribution assembly 220 may include a plurality of separate injector units 221, each injector unit 221 being capable of depositing a film or part of a film on the wafer 260, as the wafer is moved beneath the injector unit 221. FIG. 7 shows a perspective view of a carousel-type processing chamber 200. Two pie-shaped injector units 221 are shown positioned on approximately opposite sides of and above the susceptor assembly 230. This number of injector units 221 is shown for illustrative purposes only. It will be understood that more or less injector units 221 can be included. In some embodiments, there are a sufficient number of pie-shaped injector units 221 to form a shape conforming to the shape of the susceptor assembly 230. In some embodiments, each of the individual pie-shaped injector units 221 may be independently moved, removed and/or replaced without affecting any of the other injector units 221. For example, one segment may be raised to permit a robot to access the region between the susceptor assembly 230 and gas distribution assembly 220 to load/unload wafers 260.

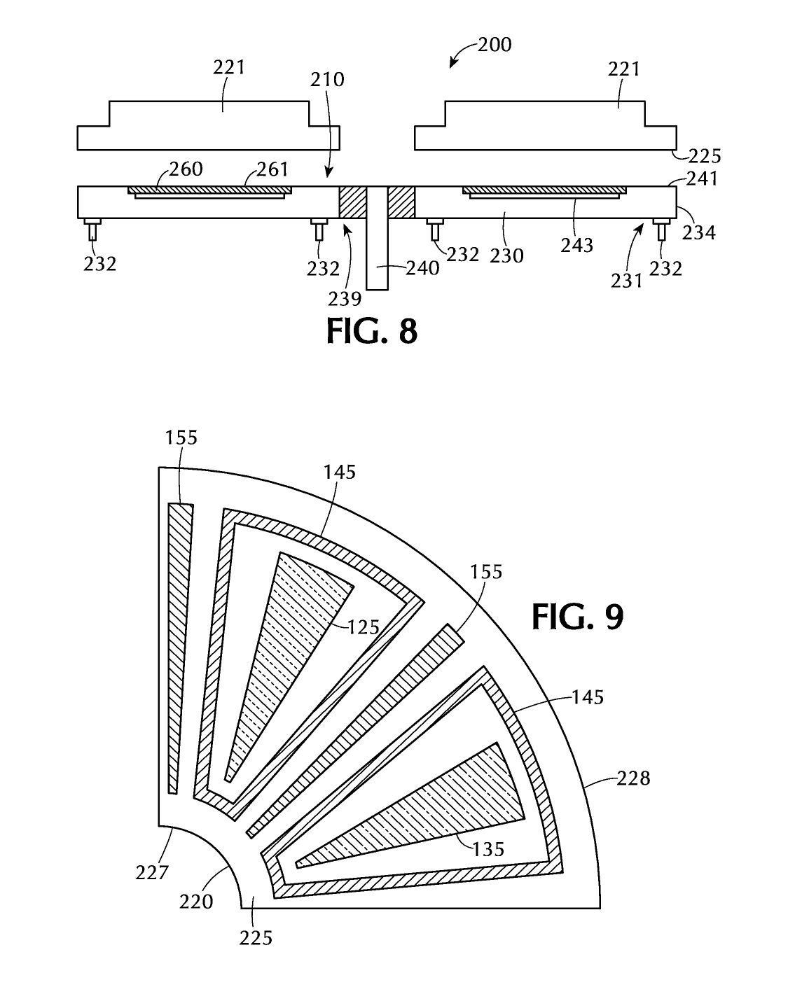

FIG. 8 shows another embodiment of the invention in which the susceptor assembly 230 is not a rigid body. In some embodiments, the susceptor assembly 230 has a droop tolerance of not more than about 0.1 mm, or not more than about 0.05 mm, or not more than about 0.025 mm, or not more than about 0.01 mm. Here, there are actuators 232 placed at the outer diameter region 231 and at the inner diameter region 239 of the susceptor assembly 230. The actuators 232 can be positioned at any suitable number of places around the inner and outer periphery of the susceptor assembly 230. In some embodiments, the actuators 232 are placed at three locations at both the outer diameter region 231 and the inner diameter region 239. The actuators 232 at both the outer diameter region 231 and the inner diameter region 239 apply pressure to the susceptor assembly 230.

Referring now to FIGS. 9 through 12, one or more embodiments of the invention are directed to a processing chamber comprising a circular gas distribution assembly with a diverter and a susceptor assembly. The circular gas distribution assembly 220, a portion of which can be seen in FIG. 9 is positioned within the processing chamber and comprises a plurality of elongate gas ports 125, 135, 145 in a front surface 225 of the gas distribution assembly 220. The plurality of elongate gas ports 125, 135, 145 extend from an area adjacent the inner peripheral edge 227 toward an area adjacent the outer peripheral edge 228 of the gas distribution assembly 220. The plurality of gas ports shown in FIG. 9 include a first reactive gas port 125, a second reactive gas port 135, a purge gas port 145 which surrounds each of the first reactive gas ports and the second reactive gas ports and vacuum ports 155.

A susceptor assembly 230 is positioned within the processing chamber to rotate at least one substrate in a substantially circular path about a rotational axis. As used in this specification and the appended claims, the term “substantially circular” means that the path is intended to be circular if the substrate were to complete a full rotation. The susceptor assembly has a top surface 241 (as shown in FIG. 8) defined by an inner peripheral edge 229 and an outer peripheral edge 231. The susceptor assembly 230 is positioned below the gas distribution assembly 220 so that the top surface 241 of the susceptor assembly 230 faces the front surface 225 of the gas distribution assembly 220.

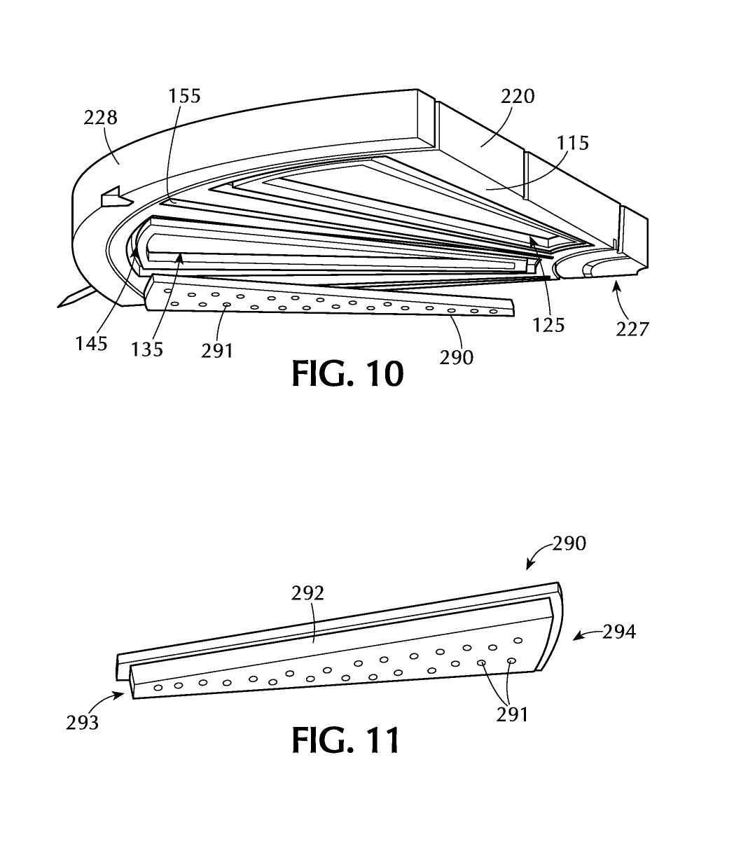

A diverter 290, shown in FIGS. 10-12, is positioned to change the flow direction of the reactive gas so that when a substrate is on the susceptor assembly 230, the reactive gas contacts the surface 261 of the wafer 260 at an angle of less than about 90° relative to the substrate surface. The angle is measured from either a rotational or radial orientation relative to the susceptor assembly 230. In a typical processing chamber, the gas flow is intended to contact the surface of the substrate at 90°. Here, the diverter 290 causes the gas flow to be skewed so that it is not 90°.

The direction that the diverter 290 changes the flow of reactive gas can be varied. In some embodiments, the flow is directed along the direction of rotation (forward), against the direction of rotation (backward), toward the inner peripheral edge (inward) or the outer peripheral edge (outward). In one or more embodiments, the diverter causes the flow of reactive gas to be angled inward and backward, or inward and forward, or outward and backward or outward and forward.

The diverter 290 can change the flow direction by incorporating angled apertures 291 or by using straight apertures 291 but positioned on an angle. FIG. 10 shows a diverter 290 being positioned at a front surface 225 of the gas distribution assembly 220. The diverter 290 can be positioned at the front surface 225 to be approximately coplanar with the front surface or can be positioned within the gas port 125, 135.

In some embodiments, the diverter 290 changes the flow of gas along the direction of rotation of the susceptor assembly. The angle that the gas can be diverted to can be any angle less than about 90° relative to the surface of the substrate. In some embodiments, the angle is greater than about 45°, or 50°, or 55°, or 60°, or 65°, or 70°, or 75°, or 80° or 85°. In some embodiments the angle is in the range of about 45° to about 89°, or in the range of about 55° to about 89°, or in the range of about 70° to about 89°.

In some embodiments, the diverter 290 changes the flow of gas to be directed against the direction of rotation of the susceptor assembly. The angle that the gas can be diverted to can be any angle less than about 90° relative to the surface of the substrate. In some embodiments, the angle is greater than about 45°, or 50°, or 55°, or 60°, or 65°, or 70°, or 75°, or 80° or 85°. In some embodiments the angle is in the range of about 45° to about 89°, or in the range of about 55° to about 89°, or in the range of about 70° to about 89°.

In some embodiments, the diverter 290 changes the flow of gas to be directed toward the inner peripheral edge of the susceptor assembly. The angle that the gas can be diverted to can be any angle less than about 90° relative to the surface of the substrate. In some embodiments, the angle is greater than about 45°, or 50°, or 55°, or 60°, or 65°, or 70°, or 75°, or 80° or 85°. In some embodiments the angle is in the range of about 45° to about 89°, or in the range of about 55° to about 89°, or in the range of about 70° to about 89°.

In some embodiments, the diverter 290 changes the flow of gas to be directed toward the outer peripheral edge of the susceptor assembly. The angle that the gas can be diverted to can be any angle less than about 90° relative to the surface of the substrate. In some embodiments, the angle is greater than about 45°, or 50°, or 55°, or 60°, or 65°, or 70°, or 75°, or 80° or 85°. In some embodiments the angle is in the range of about 45° to about 89°, or in the range of about 55° to about 89°, or in the range of about 70° to about 89°.

The diverter 290 can also change the flow of gas along any of the previous directions in combinations of along or against the rotation and toward the inner peripheral edge or outer peripheral edge.

FIG. 11 shows a diverter 290 that can be attached to a front surface 225 of a gas distribution assembly. The diverter 290 includes a body 292 with an inner peripheral edge 293 and an outer peripheral edge 294. This diverter 290 can be attached to the front surface of the gas distribution assembly so that the angle of gas flow is fixed at a single angle, or can be connected to a controller that can cause the diverter to be tilted to change the flow direction.

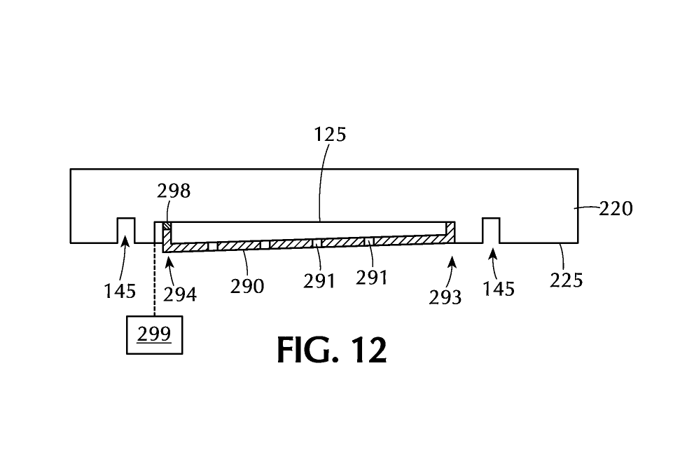

Referring to FIG. 12, a portion of a gas distribution assembly 220 is shown in cross-section. A diverter 290 is shown positioned within the reactive gas port 125. An actuator 298 is connected to the outer peripheral edge 294 of the diverter 290 and is in electrical communication with a diverter controller 299. While only one actuator 298 is shown, it will be understood that the diverter controller 299 can control any number of actuators to provide full control over the tilt of the diverter 290. The embodiment shown in FIG. 12 has the outer peripheral edge 294 of the diverter 290 extending further from the front surface 225 of the assembly 220 than the inner peripheral edge 293 of the diverter 290. This will cause the reactive gas passing through the diverter to be angled toward the inner peripheral edge of the susceptor assembly. Additional actuators 298 can be included which allow the diverter to be tilted both within and normal to the orientation of the Figure.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not be required. Indeed, other embodiments relate to deposition processes under very mild conditions without a plasma.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus are disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

While the foregoing is directed to embodiments of the present invention, other and further embodiments of the invention may be devised without departing from the basic scope thereof, and the scope thereof is determined by the claims that follow.

What is claimed is:

1. A processing chamber comprising:
a circular gas distribution assembly positioned within the processing chamber, the gas distribution assembly comprising a plurality of elongate gas ports in a front face of the gas distribution assembly, the plurality of elongate gas ports extending from an inner diameter region to an outer diameter region of the gas distribution assembly, the plurality of gas ports comprising a reactive gas port to deliver a reactive gas to the processing chamber, a purge gas port to deliver a purge gas to the processing chamber and a vacuum port to evacuate gases from the processing chamber;
a susceptor assembly within the processing chamber to rotate at least one substrate in a substantially circular path about a rotational axis, the susceptor assembly having a top surface defined by an inner peripheral edge and an outer peripheral edge, the susceptor assembly positioned below the gas distribution assembly so that the top surface of the susceptor assembly faces the front face of the gas distribution assembly; and
a diverter positioned to change a direction of flow of the reactive gas so that when a substrate is on the susceptor assembly, the reactive gas contacts a surface of the substrate at an angle of less than about 90° relative to the substrate surface.

2. The processing chamber of claim 1, wherein the diverter changes the flow of reactive gas to be angled in a direction of rotation of the susceptor assembly.

3. The processing chamber of claim 1, wherein the diverter changes the flow of reactive gas to be angled in a direction opposite of rotation of the susceptor assembly.

4. The processing chamber of claim 1, wherein the diverter changes the flow of reactive gas to be angled toward the inner peripheral edge of the susceptor assembly.

5. The processing chamber of claim 1, wherein the diverter changes the flow of reactive gas to be angled toward the outer peripheral edge of the susceptor assembly.

6. The processing chamber of claim 1, wherein the diverter changes the flow of reactive gas to be angled toward the inner peripheral edge of the susceptor assembly and against a direction of rotation of the susceptor assembly.

7. The processing chamber of claim 1, wherein the diverter changes the flow of reactive gas to be angled toward the outer peripheral edge of the susceptor assembly and along a direction of rotation of the susceptor assembly.

8. The processing chamber of claim 1, wherein the diverter changes the flow of reactive gas to be angled toward the outer peripheral edge of the susceptor assembly and against a direction of rotation of the susceptor assembly.

9. The processing chamber of claim 1, wherein the diverter changes the flow of reactive gas to be angled toward the inner peripheral edge of the susceptor assembly and along a direction of rotation of the susceptor assembly.

10. The processing chamber of claim 1, wherein the angle is in the range of about 70° to about 89°.

11. The processing chamber of claim 1, wherein the diverter is inserted into the reactive gas port.

12. The processing chamber of claim 1, wherein the diverter is positioned at the front face of the gas distribution assembly adjacent the reactive gas port.

13. The processing chamber of claim 1, further comprising a diverter controller to control one or more of the direction of the reactive gas flow and the angle of the reactive gas flow.

14. The processing chamber of claim 1, wherein the susceptor comprises a plurality of recesses sized to support a substrate.

15. The processing chamber of claim 14, wherein the recesses are sized so that a top surface of the substrate is substantially coplanar with a top surface of the susceptor.

16. A processing chamber comprising:
a circular gas distribution assembly positioned within the processing chamber, the gas distribution assembly comprising a plurality of elongate gas ports in a front face of the gas distribution assembly, the plurality of elongate gas ports extending from an inner diameter region to an outer diameter region of the gas distribution assembly, the plurality of gas ports comprising a reactive gas port to deliver a reactive gas to the processing chamber, a purge gas port to deliver a purge gas to the processing chamber and a vacuum port to evacuate gases from the processing chamber;
a susceptor assembly within the processing chamber to rotate at least one substrate in a substantially circular path about a rotational axis, the susceptor assembly having a top surface defined by an inner peripheral edge and an outer peripheral edge with a plurality of recesses sized to support a substrate so that a top surface of the substrate is substantially coplanar with the top surface of the susceptor assembly, the susceptor assembly positioned below the gas distribution assembly so that the top surface of the susceptor assembly faces the front face of the gas distribution assembly;
a diverter positioned to change a direction of flow of the reactive gas so that when a substrate is on the susceptor assembly, the reactive gas contacts a surface of the substrate at an angle in the range of about 70° to about 89° relative to the substrate surface in a direction opposite of rotation of the susceptor assembly and toward an inner peripheral edge of the susceptor assembly; and
a diverter controller to control one or more of the direction of the reactive gas flow and the angle of the reactive gas flow.

17. A method of processing a plurality of substrates, the method comprising:
rotating a susceptor assembly in a processing direction to pass each of the plurality of substrates adjacent a front face of a gas distribution assembly to expose the substrates to a flow of reactive gas from the gas distribution assembly; and
controlling a diverter to angle the flow of reactive gas to less than about 90° relative to a surface of the substrate.

18. The method of claim 17, wherein controlling the diverter causes the flow of reactive gas to be angled in the range of about 70° to about 89° relative to the surface of the substrate surface.

19. The method of claim 17, wherein controlling the diverter causes the flow of reactive gas to be angled against the processing direction.

20. The method of claim 17, wherein controlling the diverter causes the flow of reactive gas to be angled either toward an inner peripheral edge of the susceptor assembly or an outer peripheral edge of the susceptor assembly.
